(19) United States
(12) Patent Application Publication
(10) Pub. No.: US 2026/0005653 A1
(43) Pub. Date: Jan. 1, 2026

(54) SWITCH PROTECTED LOW NOISE AMPLIFIERS

(71) Applicant: Analog Devices International Unlimited Company, Co. Limerick (IE)

(72) Inventors: Ilker Kalyoncu, Istanbul (TR); Huseyin Kayahan, Istanbul (TR)

(21) Appl. No.: 18/758,079

(22) Filed: Jun. 28, 2024

(51) Int. Cl. H03F 1/52; H03F 3/19; H04B 1/10

(52) U.S. Cl. CPC H03F 1/52; H03F 3/19; H04B 1/1027; H03F 2200/294; H03F 2200/426; H03F 2200/451

(57) ABSTRACT

Switch protected low noise amplifiers (LNAs) are disclosed herein. In certain embodiments, a switch protected LNA includes an antenna terminal for receiving a radio frequency (RF) signal, an LNA for amplifying the RF signal, a first input inductor, a second input inductor, an inductor bypass switch connected in parallel to the second input inductor, and a shunt protection switch. The first input inductor is electrically connected between the antenna terminal and the second input inductor, while the second input inductor is electrically connected between the first input inductor and the shunt protection switch. The inductor bypass switch is turned on and the shunt protection switch is turned off in a receive mode, while the inductor bypass switch is turned off and the shunt protection switch is turned on in a transmit mode.

### FIELD OF THE DISCLOSURE

Embodiments of the invention relate to electronic systems, and more particularly, to switch protected low noise amplifiers for radio frequency (RF) communications.

### BACKGROUND

An RF communication system can include one or more low noise amplifiers (LNAs) for providing signal amplification to received signals. For example, an LNA can be used in an RF communication system to amplify relatively weak signals received by an antenna. The LNA can operate to provide initial amplification in a receive path to increase signal-to-noise ratio (SNR) of the received RF signal by providing gain to the signal while introducing a relatively small amount of noise. A protection switch can be included at an input of an LNA to protect the LNA from damage arising from any reflections and/or transmit signal leakage occurring when the RF communication system is transmitting. An LNA protected by a protection switch is referred to as a switch protected LNA.

Examples of RF communication systems with one or more switch protected LNAs include, but are not limited to, base stations, mobile devices (for instance, smartphones or handsets), laptop computers, tablets, and wearable electronics.

### SUMMARY OF THE DISCLOSURE

Switch protected low noise amplifiers (LNAs) are disclosed herein. In certain embodiments, a switch protected LNA includes an antenna terminal for receiving a radio frequency (RF) signal, an LNA for amplifying the RF signal, a first input inductor, a second input inductor, an inductor bypass switch connected in parallel to the second input inductor, and a shunt protection switch. The first input inductor is electrically connected between the antenna terminal and the second input inductor, while the second input inductor is electrically connected between the first input inductor and the shunt protection switch. The inductor bypass switch is turned on and the shunt protection switch is turned off in a receive mode, while the inductor bypass switch is turned off and the shunt protection switch is turned on in a transmit mode. By implementing the switch protected LNA in this manner, the second input inductor is in series with the first input inductor in the transmit mode to provide additional inductance that improves transmit mode bandwidth. Furthermore, the second input inductor is bypassed in the receive mode to provide low insertion loss and improved receive noise figure (NF). Accordingly, the switch protected LNA can be used to achieve good receive mode NF, wide receive mode bandwidth, and/or wide transmit mode bandwidth.

In one aspect, a switch protected low noise amplifier (LNA) includes an antenna terminal configured to receive a radio frequency (RF) signal, an LNA configured to amplify the RF signal, a first input inductor, a second input inductor, an inductor bypass switch electrically connected in parallel to the second input inductor, and a shunt protection switch. The first input inductor is electrically connected between the antenna terminal and the second input inductor, and the second input inductor electrically connected between the first input inductor and the shunt protection switch. The inductor bypass switch is configured to turn on and the shunt protection switch is configured to turn off in a receive mode of the switch protected LNA, and the inductor bypass switch is configured to turn off and the shunt protection switch is configured to turn on in a transmit mode of the switch protected LNA.

In another aspect, a front end system includes a circulator and a switch protected low noise amplifier (LNA) that includes an antenna terminal configured to receive a radio frequency (RF) signal from a receive port of the circulator, an LNA configured to amplify the RF signal, a first input inductor, a second input inductor, an inductor bypass switch electrically connected in parallel to the second input inductor, and a shunt protection switch. The first input inductor is electrically connected between the antenna terminal and the second input inductor, and the second input inductor electrically connected between the first input inductor and the shunt protection switch. The inductor bypass switch is configured to turn on and the shunt protection switch is configured to turn off in a receive mode of the switch protected LNA, and the inductor bypass switch is configured to turn off and the shunt protection switch is configured to turn on in a transmit mode of the switch protected LNA.

In another aspect, a method of protecting a low noise amplifier (LNA) includes receiving a radio frequency (RF) signal at an antenna terminal and turning on an inductor bypass switch and turning off a shunt protection switch in a receive mode of a switch protected LNA, wherein a first input inductor is electrically connected between the antenna terminal and a second input inductor, the second input inductor is electrically connected between the first input inductor and the shunt protection switch, and the inductor bypass switch is electrically connected in parallel to the second input inductor. The method further includes amplifying the RF signal using an LNA in the receive mode, the RF signal received by the LNA through the first input inductor. The method further includes turning off the inductor bypass switch and turning on the shunt protection switch in a transmit mode of the switch protected LNA.

In another aspect, a switch protected low noise amplifier (LNA) includes an antenna terminal configured to receive a radio frequency (RF) signal, an LNA configured to amplify the RF signal, an input inductor, a bypass switch electrically connected in series with the input inductor between the antenna terminal and an input of the LNA, and a shunt protection switch electrically connected between the input of the LNA and a ground voltage. The bypass switch is configured to turn off and the shunt protection switch is configured to turn off in a receive mode of the switch protected LNA, and the bypass switch is configured to turn on and the shunt protection switch is configured to turn on in a transmit mode of the switch protected LNA.

In another aspect, a front end system includes a circulator and a switch protected low noise amplifier (LNA) that includes an antenna terminal configured to receive a radio frequency (RF) signal from the circulator, an LNA configured to amplify the RF signal, an input inductor, a bypass switch electrically connected in series with the input inductor between the antenna terminal and an input of the LNA, and a shunt protection switch electrically connected between the input of the LNA and a ground voltage. The bypass switch is configured to turn off and the shunt protection switch is configured to turn off in a receive mode of the switch protected LNA, and the bypass switch is configured to turn on and the shunt protection switch is configured to turn on in a transmit mode of the switch protected LNA.

In another aspect, a method of protecting a low noise amplifier (LNA) is provided. The method includes receiving a radio frequency (RF) signal at an antenna terminal and turning off a bypass switch and turning off a shunt protection switch in a receive mode of a switch protected LNA, the bypass switch electrically connected in series with an input inductor between the antenna terminal and an input of an LNA, and the shunt protection switch electrically connected between the input of the LNA and a ground voltage. The method further includes amplifying the RF signal using the LNA in the receive mode, the RF signal received by the LNA through the input inductor, and turning on the bypass switch and turning on the shunt protection switch in a transmit mode of the switch protected LNA.

### BRIEF DESCRIPTION OF THE DRAWINGS

FIG. 1 is a schematic diagram of one embodiment of a phased array antenna system.

FIG. 2 is a schematic diagram of one embodiment of a front end system.

FIG. 3 is a schematic diagram of one embodiment of a switch protected low noise amplifier (LNA).

FIG. 4 is a schematic diagram of another embodiment of a switch protected LNA.

FIG. 5 is a schematic diagram of another embodiment of a switch protected LNA.

FIG. 6A is a schematic diagram of another embodiment of a switch protected LNA.

FIG. 6B is a schematic diagram of another embodiment of a switch protected LNA.

FIG. 6C is a schematic diagram of another embodiment of a switch protected LNA.

FIG. 7 is a schematic diagram of another embodiment of a switch protected LNA.

FIG. 8 is a schematic diagram of another embodiment of a switch protected LNA.

FIG. 9 is a schematic diagram of another embodiment of a switch protected LNA.

FIG. 10A is a graph of one example of return loss versus frequency in transmit mode for one implementation of a switch protected LNA.

FIG. 10B is a graph of one example of noise figure versus frequency in receive mode for one implementation of a switch protected LNA.

FIG. 10C is a graph of one example of return loss versus frequency in receive mode for one implementation of a switch protected LNA.

FIG. 11A is a schematic diagram of another embodiment of a switch protected LNA.

FIG. 11B is a schematic diagram of another embodiment of a switch protected LNA.

FIG. 12A is a schematic diagram of another embodiment of a switch protected LNA.

FIG. 12B is a schematic diagram of another embodiment of a switch protected LNA.

### DETAILED DESCRIPTION OF EMBODIMENTS

The following detailed description of embodiments presents various descriptions of specific embodiments of the invention. However, the invention can be embodied in a multitude of different ways. In this description, reference is made to the drawings. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

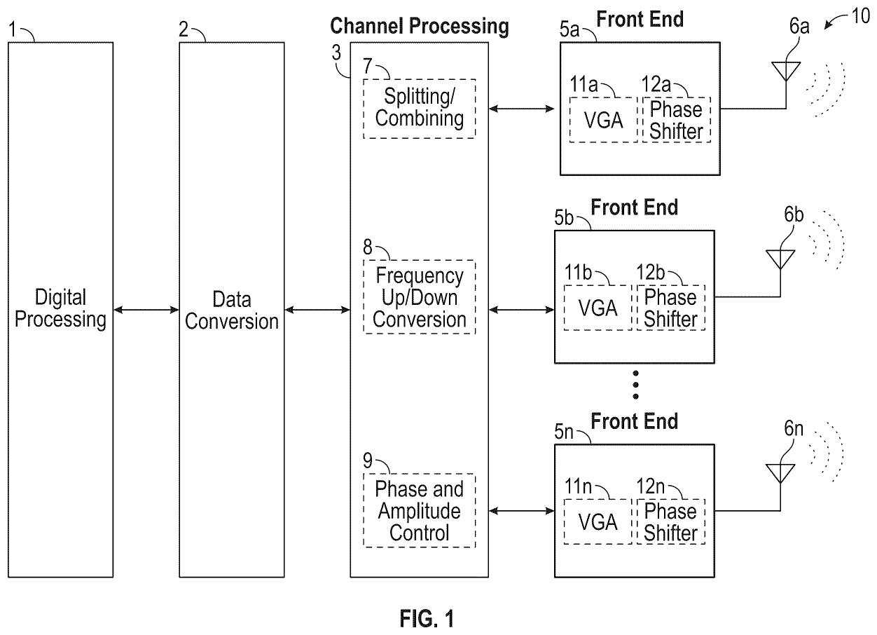

FIG. 1 is a schematic diagram of one embodiment of a phased array antenna system 10. The phased array antenna system 10 includes a digital processing circuit 1, a data conversion circuit 2, a channel processing circuit 3, RF front ends 5a, 5b, . . . 5n, and antennas 6a, 6b, . . . 6n. Although an example system with three RF front ends and three antennas is illustrated, the phased array antenna system 10 can include more or fewer RF front ends and/or more or fewer antennas as indicated by the ellipses. Furthermore, in certain implementations, the phased array antenna system 10 is implemented with separate antennas for transmitting and receiving signals.

The phased array antenna system 10 illustrates one embodiment of an electronic system that can include one or more antennas implemented in accordance with the teachings herein. However, the antennas disclosed herein can be used in a wide range of electronics. A phased array antenna system is also referred to herein as an active scanned electronically steered array or beamforming communication system.

As shown in FIG. 1, the channel processing circuit 3 is coupled to antennas 6a, 6b, . . . 6n through RF front ends 5a, 5b, . . . 5n, respectively. The channel processing circuit 3 includes a splitting/combining circuit 7, a frequency up/down conversion circuit 8, and a phase and amplitude control circuit 9, in this embodiment. The channel processing circuit 3 provides RF signal processing of RF signals transmitted by and received from each communication channel. In the illustrated embodiment, each communication channel is associated with a corresponding RF front end and antenna. However, other implementations are possible.

With continuing reference to FIG. 1, the digital processing circuit 1 generates digital transmit data for controlling a transmit beam radiated from the antennas 6a, 6b, . . . 6n. The digital processing circuit 1 also processes digital receive data representing a receive beam received by the antennas 6a, 6b, . . . 6n. In certain implementations, the digital processing circuit 1 includes one or more baseband processors.

As shown in FIG. 1, the digital processing circuit 1 is coupled to the data conversion circuit 2, which can include digital-to-analog converter (DAC) circuitry for converting digital transmit data to one or more baseband transmit signals and analog-to-digital converter (ADC) circuitry for converting one or more baseband receive signals to digital receive data.

The frequency up/down conversion circuit 8 provides frequency upshifting from baseband to RF and frequency downshifting from RF to baseband, in this embodiment. However, other implementations are possible, such as configurations in which the phased array antenna system 10 operates in part at an intermediate frequency (IF) or in which RF data converters provide direct conversion between digital and RF. In certain implementations, the splitting/combining circuit 7 provides splitting to one or more frequency upshifted transmit signals to generate RF signals suitable for processing by the RF front ends 5a, 5b, . . . 5n and subsequent transmission on the antennas 6a, 6b, . . . 6n. Additionally, the splitting/combining circuit 7 combines RF signals received vias the antennas 6a, 6b, . . . 6n and RF front ends 5a, 5b, . . . 5n to generate one or more baseband receive signals for the data conversion circuit 2.

The channel processing circuit 3 also includes the phase and amplitude control circuit 9 for controlling beamforming operations. For example, the phase and amplitude control circuit 9 controls the amplitudes and phases of RF signals transmitted or received via the antennas 6a, 6b, . . . 6n to provide beamforming.

With respect to signal transmission, the RF signals radiated from the antennas 6a, 6b, . . . 6n aggregate through constructive and destructive interference to collectively generate a transmit beam having a particular direction. With respect to signal reception, the channel processing circuit 3 generates a receive beam by combining the RF signals received from the antennas 6a, 6b, . . . 6n after amplitude scaling and phase shifting.

Phased array antenna systems are used in a wide variety of applications including, but not limited to, mobile communications, military and defense systems, and/or radar technology.

As shown in FIG. 1, the RF front ends 5a, 5b, . . . 5n each include one or more VGAs 11a, 11b, . . . 11n, which are used to scale the amplitude of RF signals transmitted or received by the antennas 6a, 6b, . . . 6n, respectively. Additionally, the RF front ends 5a, 5b, . . . 5n each include one or more phase shifters 12a, 12b, . . . 12n, respectively, for phase-shifting the RF signals. For example, in certain implementations, the phase and amplitude control circuit 9 generates gain control signals for controlling the amount of gain provided by the VGAs 11a, 11b, . . . 11n and phase control signals for controlling the amount of phase shifting provided by the phase shifters 12a, 12b, . . . 12n.

The RF front ends 5a, 5b, . . . 5n depict example front end systems that can be implemented to include one or more switch protected LNAs implemented in accordance with the teachings herein. Such switch protected LNAs can provide amplification to RF receive signals received on the antennas 6a, 6b, . . . 6n. Although switch protected LNAs can be included in the RF front ends 5a, 5b, . . . 5n of FIG. 1, the teachings herein are applicable to other types of RF communication systems and front ends.

The phased array antenna system 10 operates to generate a transmit beam and/or receive beam including a main lobe pointed in a desired direction of communication. The phased array antenna system 10 realizes increased signal to noise (SNR) ratio in the direction of the main lobe. The transmit beam and/or receive beam also includes one or more side lobes, which point in different directions than the main lobe and are undesirable.

An accuracy of beam direction of the phased array antenna system 10 is based on a precision in controlling the gain and phases of the RF signals communicated via the antennas 6a, 6b, . . . 6n. For example, when one or more of the RF signals has a large phase error, the beam can be broken and/or pointed in an incorrect direction. Furthermore, the size or magnitude of beam side lobe levels is based on an accuracy in controlling the phases and amplitudes of the RF signals.

Accordingly, it is desirable to tightly control the phase and amplitude of RF signals communicated by the antennas 6a, 6b, . . . 6n to provide robust beamforming operations.

Although the phased array antenna system 10 of FIG. 1 depicts one example of an RF communication system that can include antennas, the teachings herein are also applicable to other types of RF communication systems.

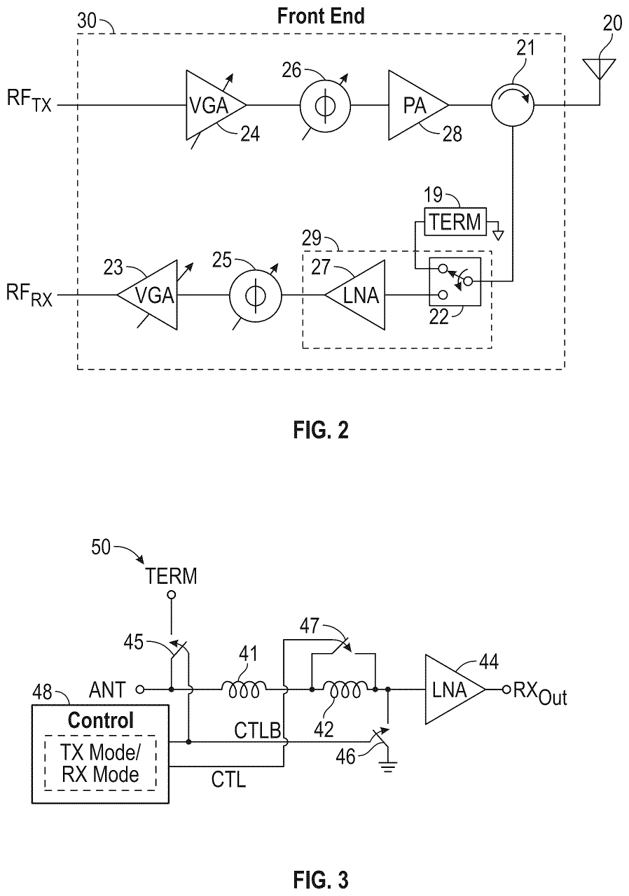

FIG. 2 is a schematic diagram of one embodiment of a front end system 30. The front end system 30 includes a termination impedance 19, a circulator 21, a receive-path VGA 23, a transmit-path VGA 24, a receive-path controllable phase shifter 25, a transmit-path phase shifter 26, a switch protected LNA 29, and a power amplifier (PA) 28. As shown in FIG. 2, the front end system 30 is depicted as being coupled to an antenna 20.

As shown in FIG. 2, the switch protected LNA 29 includes a protection switch 22 and an LNA 27. The switch protected LNA 29 can be implemented in accordance with any of the embodiments herein. Although FIG. 2 depicts one example of a front-end system that can transmit and receive RF signals, the switch protected antenna 29 can be included in a wide variety of types of RF front ends. Accordingly, other implementations are possible.

The front end system 30 can be included in a wide variety of RF systems, including, but not limited to, phased array antenna systems, such as the phased array antenna system 10 of FIG. 1. For example, multiple instantiations of the front end system 30 can be used to implement the RF front ends 5a, 5b, . . . 5n of FIG. 1. In certain implementations, two or more instantiations of the switch protected LNA 29 are fabricated on the same semiconductor die or chip. Thus, switch protected LNAs associated with two or more different channels of a phased array antenna system can be fabricated on the same semiconductor die.

As shown in FIG. 2, the front end system 30 includes the receive-path VGA 23 for outputting an RF receive signal RF_{RX} (which corresponds to an amplified receive signal from the antenna 20), and the transmit-path VGA 24 for controlling an amount of amplification provided to an RF transmit signal RF_{TX} to be transmitted on the antenna 20. Additionally, the front end system 30 includes the receive-path controllable phase shifter 25 for controlling an amount of phase shift to the RF receive signal RF_{RX}, and the transmit-path controllable phase shifter 26 for controlling an amount of phase shift provided to the RF transmit signal RF_{TX}.

The gain control provided by the VGAs and the phase control provided by the phase shifters can serve a wide variety of purposes including, but not limited to, compensating for temperature and/or process variation. Moreover, in beamforming applications, the VGAs and phase shifters can control side-lobe levels of a beam pattern.

As shown in FIG. 2, the antenna 20 is electrically connected to an antenna port of the circulator 21, the output of the power amplifier 28 is electrically connected to a transmit port of the circulator 21, and the input of the switch protected LNA 29 is electrically connected to a receive port of the circulator 21.

The protection switch 22 can connect the receive port of the circulator 21 to the input of the LNA 27 when the front end system 30 is in a receive mode and connect the receive port of the circulator 21 to the termination impedance 19 when the front end system 30 is in a transmit mode.

By controlling the protection switch 22 in this manner, the high-power transmit signal leakage coming from the power amplifier 28 in the transmit mode can be routed to the termination impedance 19, which can be, for example, an off-chip termination resistor. This in turn prevents the LNA 27 from being damaged (for instance, blowing up) due to any transmit leakage and/or reflection issues arising from either the circulator 21 or the antenna 20.

### Examples of Switch Protected LNAs

In certain embodiments herein, a switch protected LNA includes an antenna terminal for receiving an RF signal from an antenna, an LNA for amplifying the RF signal, a first input inductor, a second input inductor, an inductor bypass switch connected in parallel to the second input inductor, and a shunt protection switch. A first end of the first input inductor is electrically connected to the antenna terminal, while a second end of the first input inductor is electrically connected to a first end of the second input inductor. Additionally, a second end of the second input inductor is electrically connected to a first end of the shunt protection switch, while a second end of the shunt protection switch is electrically connected to a ground voltage. The inductor bypass switch is turned on and the shunt protection switch is turned off when the switch protected LNA operates in a receive mode, while the inductor bypass switch is turned off and the shunt protection switch is turned on when the switch protected LNA operates in a transmit mode.

By implementing the switch protected LNA in this manner, the second input inductor is in series with the first input inductor in the transmit mode to provide additional inductance that improves transmit mode bandwidth. Furthermore, the second input inductor is bypassed in the receive mode to provide low insertion loss and improved receive noise figure (NF). Accordingly, the switch protected LNA can be used to achieve good receive mode NF, wide receive mode bandwidth, and/or wide transmit mode bandwidth.

FIG. 3 is a schematic diagram of one embodiment of a switch protected LNA 50. The switch protected LNA 50 includes an antenna terminal ANT, a termination terminal TERM, a receive output terminal RX_{Out}, a first input inductor 41, a second input inductor 42, an LNA 44, a series termination switch 45, a shunt protection switch 46, an inductor bypass switch 47, and a control circuit 48.

The antenna terminal ANT is used for receiving an RF receive signal from an antenna. The RF receive signal can be received either directly from the antenna or through one or more intervening components (for instance, one or more circulators, filters, switches, diplexers, triplexers, duplexers, etc.).

With continuing reference to FIG. 3, the termination terminal TERM can be coupled to a termination impedance, which can include a termination resistor. For example, in some implementations the termination impedance can include an off-chip 50-Ohm termination resistor connected between the termination terminal TERM and a ground voltage.

The receive output terminal RX_{Out} is electrically connected to an output of the LNA 50 and is used to provide an amplified RF receive signal to one or more downstream components.

As shown in FIG. 3, the series termination switch 45 is electrically connected between the antenna terminal ANT and the termination terminal TERM, while the shunt protection switch 46 is electrically connected between an input of the LNA 44 and the ground voltage. A first end of the first input inductor 41 is electrically connected to the antenna terminal ANT, while a second end of the first input inductor 41 is electrically connected to a first end of the second input inductor 42. Additionally, a second end of the second input inductor 42 is electrically connected to a first end of the shunt protection switch 46, while a second end of the shunt protection switch 46 is electrically connected to the ground voltage.

The inductor bypass switch 47 is electrically connected in parallel to the second input inductor 42. For example, a first end of the inductor bypass switch 47 is electrically connected to the first end of the second input inductor 42, while a second end of the inductor bypass switch 47 is electrically connected to the second end of the second input inductor 42.

The LNA 50 of FIG. 3 advantageously operates without any transistors in series between the antenna terminal ANT and the input to the LNA 44 to provide lower insertion loss relative to a configuration using a single-pole double-throw (SPDT) switch. Additionally, the inductance looking into the input of the LNA 44 from the antenna terminal ANT operates in combination with a capacitance at the antenna terminal ANT to form an inductor-capacitor (LC) resonator that can be tuned to the frequency of operation. The inductance of the LC resonator determines a transmit mode bandwidth of the switch protected LNA 50.

In the illustrated embodiment, the switch protected LNA 50 is operable in a transmit mode or a receive mode. Additionally, the control circuit 48 generates a control signal CTL and an inverted control signal CTLB to open or close each of the switches based on whether the switch protected LNA 50 is operating in the transmit mode or the receive mode. In certain implementations, the control circuit 48 is coupled to one or more pins of an interface of a semiconductor die, and the interface provides data used to set the switch protected LNA 50 to operate in the transmit mode or the receive mode.

In certain implementations, when the switch protected LNA 50 is in the receive mode, the inductor bypass switch 47 is turned on (closed), while the series termination switch 45 and the shunt protection switch 46 are turned off (opened). Additionally, when the switch protected LNA 50 is in the transmit mode, the inductor bypass switch 47 is turned off, while the series termination switch 45 and the shunt protection switch 46 are turned on.

Accordingly, the second input inductor 42 is in series with the first input inductor 41 in the transmit mode to provide additional inductance that improves transmit mode bandwidth. Furthermore, the second input inductor 42 is bypassed in the receive mode to provide low insertion loss and improved receive NF. Accordingly, the switch protected LNA 50 can be used to achieve good receive mode NF, wide receive mode bandwidth, and/or wide transmit mode bandwidth.

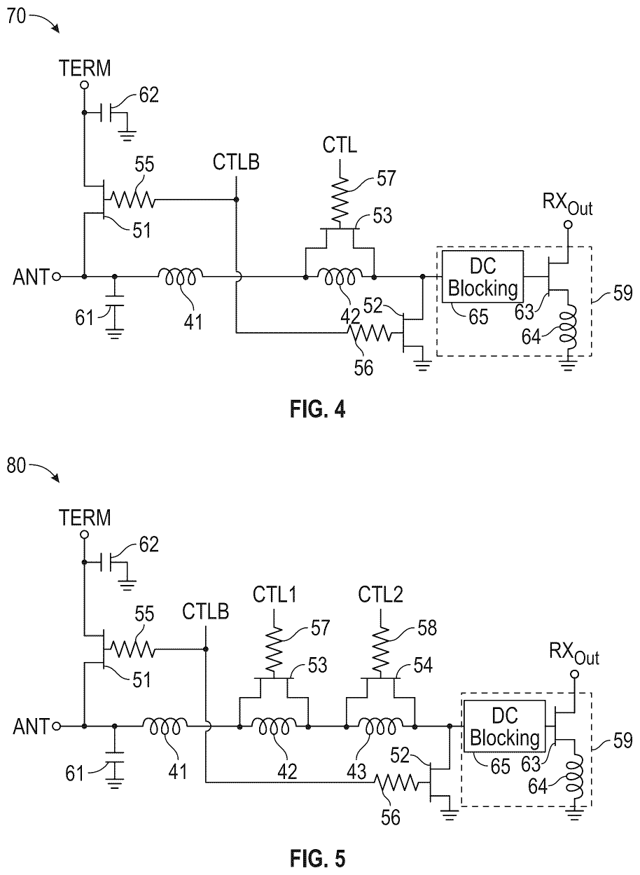

FIG. 4 is a schematic diagram of another embodiment of a switch protected LNA 70. The switch protected LNA 70 includes an antenna terminal ANT, a termination terminal TERM, a receive output terminal RX_{Out}, a first input inductor 41, a second input inductor 42, an LNA 59, a series termination switch field-effect transistor (FET) 51, a shunt protection switch FET 52, an inductor bypass switch FET 53, a series termination switch gate resistor 55, a shunt protection switch gate resistor 56, an inductor bypass switch gate resistor 57, an antenna terminal capacitor 61, and a termination terminal capacitor 62.

As shown in FIG. 4, the series termination switch FET 51 is electrically connected between the antenna terminal ANT and the termination terminal TERM and includes a gate that receives the inverted control signal CTLB through the series termination switch gate resistor 55. Additionally, the shunt protection switch FET 52 is electrically connected between an input of the LNA 59 and the ground voltage and includes a gate that receives the inverted control signal CTLB through the shunt protection switch gate resistor 56. A first end of the first input inductor 41 is electrically connected to the antenna terminal ANT, while a second end of the first input inductor 41 is electrically connected to a first end of the second input inductor 42. Additionally, a second end of the second input inductor 42 is electrically connected to a drain of the shunt protection switch FET 52, while a source of the shunt protection switch FET 52 is electrically connected to the ground voltage.

The inductor bypass switch FET 53 is electrically connected in parallel to the second input inductor 42. For example, a drain of the inductor bypass switch FET 53 is electrically connected to the first end of the second input inductor 42, while a source of the inductor bypass switch FET 53 is electrically connected to the second end of the second input inductor 42. The inductor bypass switch FET 53 includes a gate that receives the control signal CTL through the inductor bypass switch gate resistor 57.

In comparison to the switch protected LNA 50 of FIG. 3, the switch protected LNA 70 of FIG. 4 uses FETs to implement the switches of FIG. 3. Although each switch is illustrated as being implemented using one FET, each of the switches can be implemented using multiple FETs in series to increase power handling capability. The FETs can be implemented in a wide variety of ways, including, but not limited to, using metal-oxide-semiconductor (MOS) transistors, such as n-type MOS transistors.

With continuing reference to FIG. 4, the switch protected LNA 70 includes the antenna terminal capacitor 61 connected between the antenna terminal ANT and the ground voltage, and the termination terminal capacitor 62 connected between the termination terminal TERM and the ground voltage. Including the antenna terminal capacitor 61 and the termination terminal capacitor 62 can aid in providing impedance matching at the terminals and/or in achieving resonances for a target operating bandwidth.

In the illustrated embodiment, the LNA 59 includes a common source FET 63, a source degeneration inductor 64, and a DC blocking circuit 65. The common source FET 63 includes a gate connected to the input of the LNA 59 through the DC blocking circuit 65, which can include a DC blocking capacitor in some implementations. The common source FET 63 further includes a drain connected to the receive output terminal RX_{Out} and a source connected to the ground voltage through the source degeneration inductor 64. Although not shown in FIG. 4, the LNA 59 can be biased in any suitable way, such as using any suitable gate biasing circuit for biasing the gate of the common source FET 63. Further, the LNA 59 can receive power in any suitable way, such as using a choke inductor to provide a supply voltage to the drain of the common source FET 63.

Although one example implementation of an LNA is shown, the teachings herein can be used in combination with a wide variety of types of LNAs including, but not limited to, LNAs using a cascode topology. Accordingly, other implementations are possible.

In the illustrated embodiment, the switch protected LNA 70 is operable in a transmit mode or a receive mode. Additionally, the control signal CTL is used to turn on the inductor bypass switch FET 53 in the receive mode and turn off the inductor bypass switch FET 53 in the transmit mode. Furthermore, the inverted control signal CTLB is used to turn off the series termination switch FET 51 and the shunt protection switch FET 52 in the receive mode, and to turn on the series termination switch FET 51 and the shunt protection switch FET 52 in the transmit mode. The control signal CTL and the inverted control signal CTLB can be generated using any suitable control circuit, such as the control circuit 48 of FIG. 3.

FIG. 5 is a schematic diagram of another embodiment of a switch protected LNA 80. The switch protected LNA 80 includes an antenna terminal ANT, a termination terminal TERM, a receive output terminal RX_{Out}, a first input inductor 41, a second input inductor 42, a third input inductor 43, an LNA 59, a series termination switch FET 51, a shunt protection switch FET 52, a first inductor bypass switch FET 53, a second inductor bypass switch FET 54, a series termination switch gate resistor 55, a shunt protection switch gate resistor 56, a first inductor bypass switch gate resistor 57, a second inductor bypass switch gate resistor 58, an antenna terminal capacitor 61, and a termination terminal capacitor 62.

The switch protected LNA 80 of FIG. 5 is similar to the switch protected LNA 70 of FIG. 4, except that the switch protected LNA 80 of FIG. 5 further includes the second inductor bypass switch FET 54 connected in parallel to the third input inductor 43. Additionally, the gate of the first inductor bypass switch FET 53 receives a first control signal CTL1 through the first inductor bypass switch gate resistor 57, while the gate of the second inductor bypass switch FET 54 receives a second control signal CTL2 through the second inductor bypass switch gate resistor 58.

By controlling the first control signal CTL1 and the second control signal CTL2, different amounts of inductance can be provided between the antenna terminal ANT and the input of the LNA 59 as desired.

For example, by turning on both the first inductor bypass switch FET 53 and the second inductor bypass switch FET 54, both the second input inductor 42 and the third input inductor 43 can be bypassed to set the input inductance between the antenna terminal ANT and the input of the LNA 59 to be about equal to the inductance of the first input inductor 51. Additionally, by turning off both the first inductor bypass switch FET 53 and the second inductor bypass switch FET 54, the input inductance can be increased to be about equal to a sum of the inductances of the first input inductor 41, the second input inductor 42, and the third input inductor 43. Furthermore, intermediate input inductance values can be obtained by turning on just one of the first inductor bypass switch FET 53 or the second inductor bypass switch FET 54.

The switch protected LNA 80 provides flexible control over the input inductance between the antenna terminal ANT and the input of the LNA 59. Thus, flexibility is provided in controlling the transmit mode bandwidth and the receive mode NF.

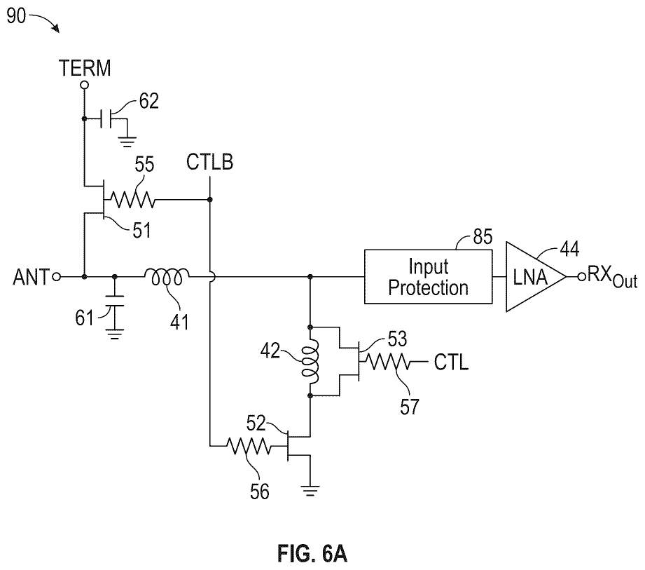

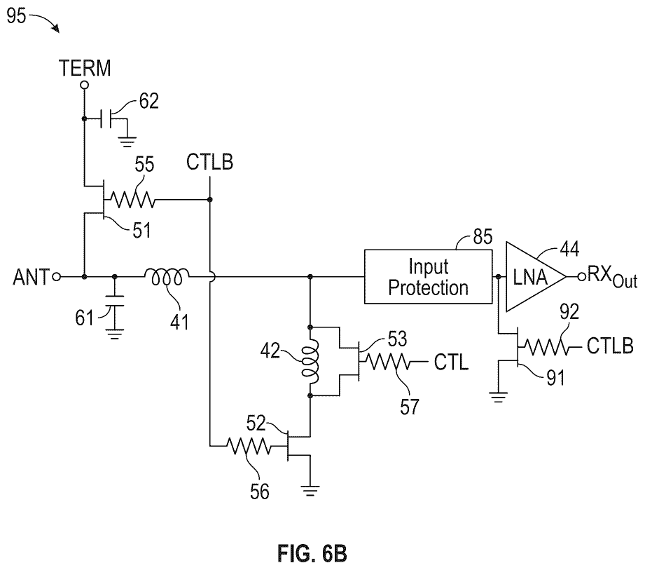

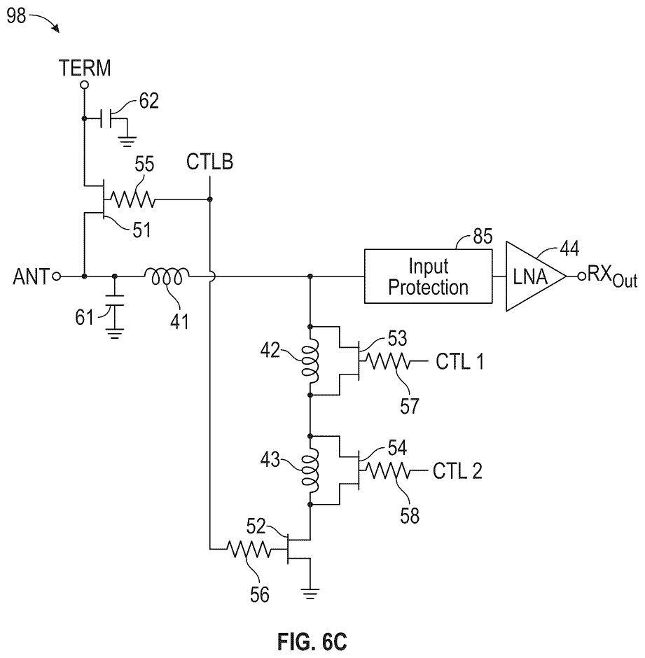

FIG. 6A is a schematic diagram of another embodiment of a switch protected LNA 90. The switch protected LNA 90 includes an antenna terminal ANT, a termination terminal TERM, a receive output terminal RX_{Out}, a first input inductor 41, a second input inductor 42, an LNA 44, a series termination switch FET 51, a shunt protection switch FET 52, an inductor bypass switch FET 53, a series termination switch gate resistor 55, a shunt protection switch gate resistor 56, an inductor bypass switch gate resistor 57, an antenna terminal capacitor 61, a termination terminal capacitor 62, and an input protection circuit 85.

The switch protected LNA 90 of FIG. 6A is similar to the switch protected LNA 70 of FIG. 4, except that the switch protected LNA 90 of FIG. 6A depicts a configuration in which the LNA 44 receives the RF receive signal from an intermediate node between first input inductor 41 and the second input inductor 42. Additionally, the input protection circuit 85 is electrically connected between the intermediate node and the input of the LNA 70 to provide enhanced protection to the LNA 44 since the second input inductor 42 is not included as part of the input series inductance of the LNA 44 when the switch protected LNA 90 is operating in the transmit mode.

FIG. 6B is a schematic diagram of another embodiment of a switch protected LNA 95. The switch protected LNA 95 includes an antenna terminal ANT, a termination terminal TERM, a receive output terminal RX_{Out}, a first input inductor 41, a second input inductor 42, an LNA 44, a series termination switch FET 51, a shunt protection switch FET 52, an inductor bypass switch FET 53, a series termination switch gate resistor 55, a shunt protection switch gate resistor 56, an inductor bypass switch gate resistor 57, an antenna terminal capacitor 61, a termination terminal capacitor 62, an input protection circuit 85, an LNA input protection switch FET 91, and an LNA input protection switch gate resistor 92.

The switch protected LNA 95 of FIG. 6B is similar to the switch protected LNA 70 of FIG. 4, except that the switch protected LNA 95 of FIG. 6B further includes the LNA input protection switch FET 91 connected between the input of the LNA 44 and ground. Additionally, a gate of the LNA input protection switch FET 91 receives an inverted control signal CTLB through the LNA input protection switch gate resistor 92.

Including the LNA input protection switch FET 91 provides further protection to the LNA 44 when the switch protected LNA 95 is operating in the transmit mode.

FIG. 6C is a schematic diagram of another embodiment of a switch protected LNA 98. The switch protected LNA 98 includes an antenna terminal ANT, a termination terminal TERM, a receive output terminal RX_{Out}, a first input inductor 41, a second input inductor 42, a third input inductor 43, an LNA 44, a series termination switch FET 51, a shunt protection switch FET 52, a first inductor bypass switch FET 53, a second inductor bypass switch FET 54, a series termination switch gate resistor 55, a shunt protection switch gate resistor 56, a first inductor bypass switch gate resistor 57, a second inductor bypass switch gate resistor 58, an antenna terminal capacitor 61, a termination terminal capacitor 62, an input protection circuit 85, an LNA input protection switch FET 91, and an LNA input protection switch gate resistor 92.

The switch protected LNA 98 of FIG. 6C is similar to the switch protected LNA 90 of FIG. 6A, except that the switch protected LNA 98 of FIG. 6C further includes the second inductor bypass switch FET 54 that is connected in parallel to the third input inductor 43. Additionally, the gate of the first inductor bypass switch FET 53 receives a first control signal CTL1 through the first inductor bypass switch gate resistor 57, while the gate of the second inductor bypass switch FET 54 receives a second control signal CTL2 through the second inductor bypass switch gate resistor 58.

By controlling the values of the first control signal CTL1 and the second control signal CTL2, different amounts of inductance can be provided as desired. For example, such controls can control the input inductance to tune to two or more frequency bands.

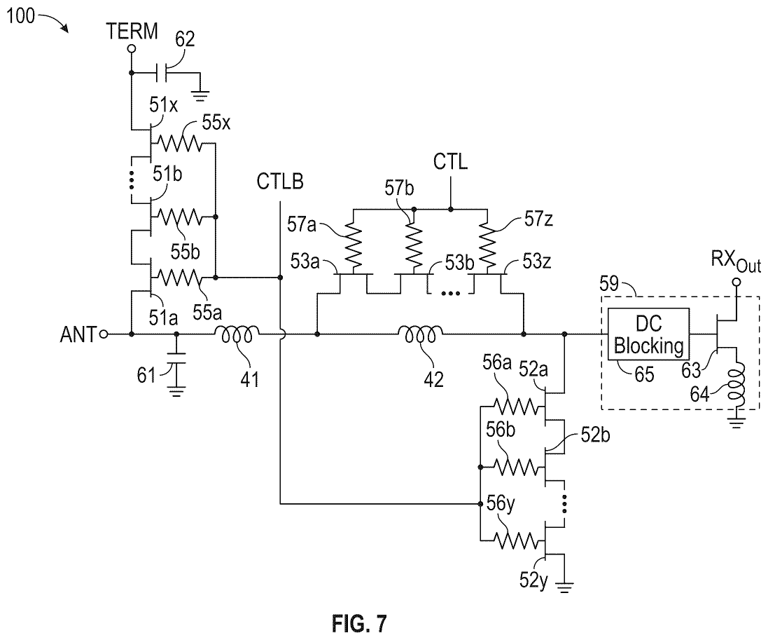

FIG. 7 is a schematic diagram of another embodiment of a switch protected LNA 100. The switch protected LNA 100 includes an antenna terminal ANT, a termination terminal TERM, a receive output terminal RX_{Out}, a first input inductor 41, a second input inductor 42, an LNA 59, series termination switch FETs 51a, 51b, . . . 51x, shunt protection switch FETs 52a, 52b, . . . 52y, inductor bypass switch FETs 53a, 53b, . . . 53z, series termination switch gate resistors 55a, 55b, . . . 55x, shunt protection switch gate resistors 56a, 56b, . . . 56y, inductor bypass switch gate resistors 57a, 57b, . . . 57z, an antenna terminal capacitor 61, and a termination terminal capacitor 62.

The switch protected LNA 100 of FIG. 7 is similar to the switch protected LNA 70 of FIG. 4, except that the switch protected LNA 100 of FIG. 7 implements each switch using multiple FETs in series. For example, the series termination switch includes x FETs in series, the shunt protection switch includes y FETs in series, and the inductor bypass switch includes z FETs in series. The numbers of FETs x, y, and z can be any desired value, which can be chosen to achieve a desired power handling capability. Any of the embodiments herein can include a switch implemented with multiple FETs in series.

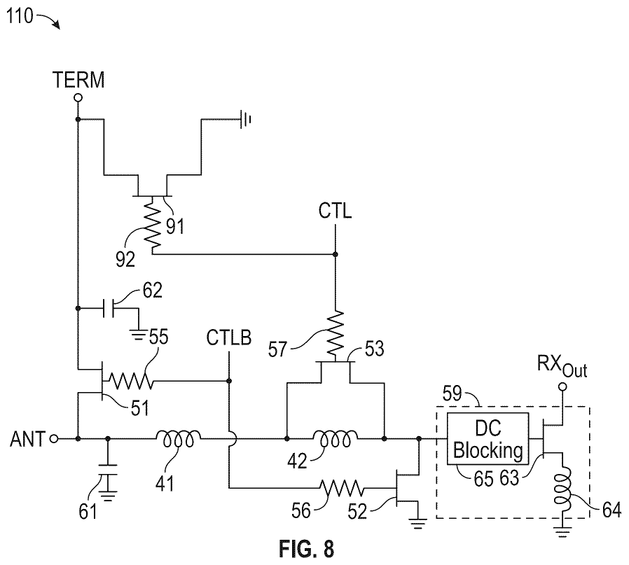

FIG. 8 is a schematic diagram of another embodiment of a switch protected LNA 110. The switch protected LNA 110 includes an antenna terminal ANT, a termination terminal TERM, a receive output terminal RX_{Out}, a first input inductor 41, a second input inductor 42, an LNA 59, a series termination switch FET 51, a shunt protection switch FET 52, an inductor bypass switch FET 53, a series termination switch gate resistor 55, a shunt protection switch gate resistor 56, an inductor bypass switch gate resistor 57, an antenna terminal capacitor 61, a termination terminal capacitor 62, a shunt termination switch FET 91, and a shunt termination switch gate resistor 92.

The switch protected LNA 110 of FIG. 8 is similar to the switch protected LNA 70 of FIG. 4, except that the switch protected LNA 110 of FIG. 8 further includes the shunt termination switch FET 91 and the shunt termination switch gate resistor 92. As shown in FIG. 8, the shunt termination switch FET 91 includes a source connected to the ground voltage, a drain connected to the termination terminal TERM, and a gate that receives the control signal CTL through the shunt termination switch gate resistor 92. By including the shunt termination switch FET 91, the termination terminal TERM is grounded in the receive mode to enhance receive mode performance, such as receive mode NF. Any of the embodiments herein can include a shunt termination switch.

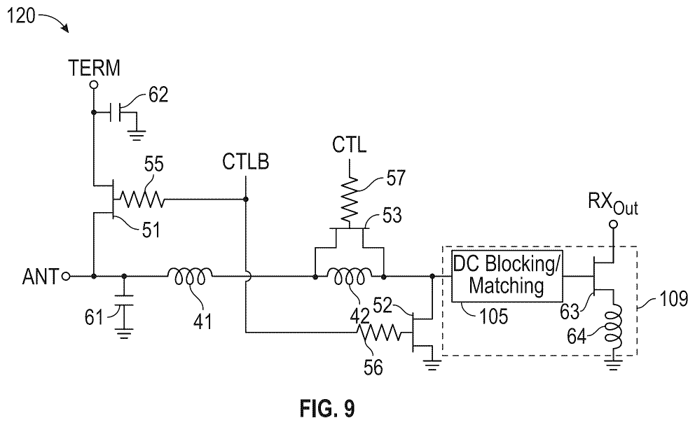

FIG. 9 is a schematic diagram of another embodiment of a switch protected LNA 120. The switch protected LNA 120 includes an antenna terminal ANT, a termination terminal TERM, a receive output terminal RX_{Out}, a first input inductor 41, a second input inductor 42, an LNA 109, a series termination switch FET 51, a shunt protection switch FET 52, an inductor bypass switch FET 53, a series termination switch gate resistor 55, a shunt protection switch gate resistor 56, an inductor bypass switch gate resistor 57, an antenna terminal capacitor 61, and a termination terminal capacitor 62.

The switch protected LNA 120 of FIG. 9 is similar to the switch protected LNA 70 of FIG. 4, except that the switch protected LNA 120 of FIG. 9 includes a different implementation of an LNA. For example, the LNA 109 of FIG. 9 includes a common source FET 63, a source degeneration inductor 64, and a DC blocking/matching circuit 105 that provides both DC blocking as well as input impedance matching to the LNA 109. Any of the embodiments herein can be implemented with an LNA that includes DC blocking and/or input impedance matching.

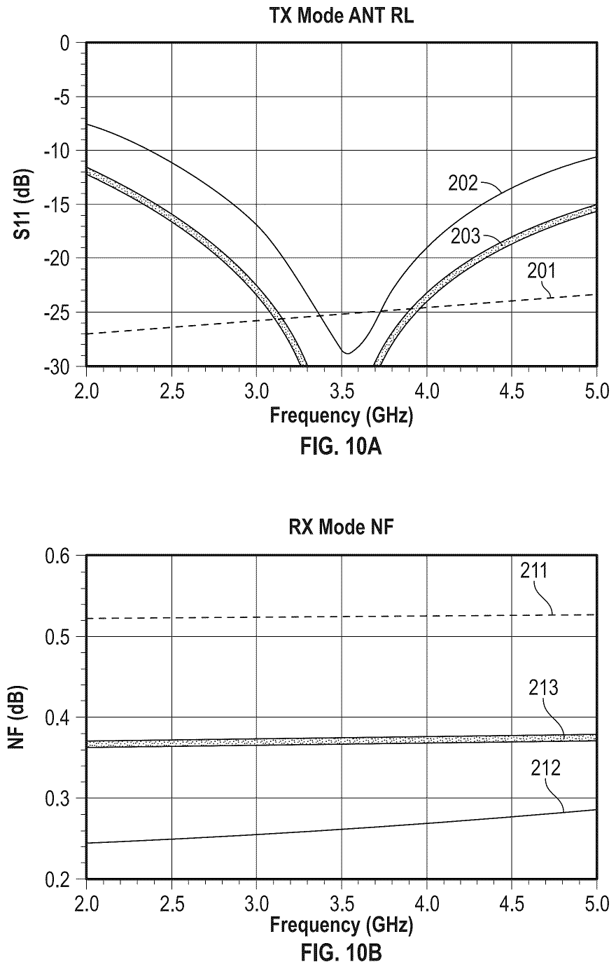

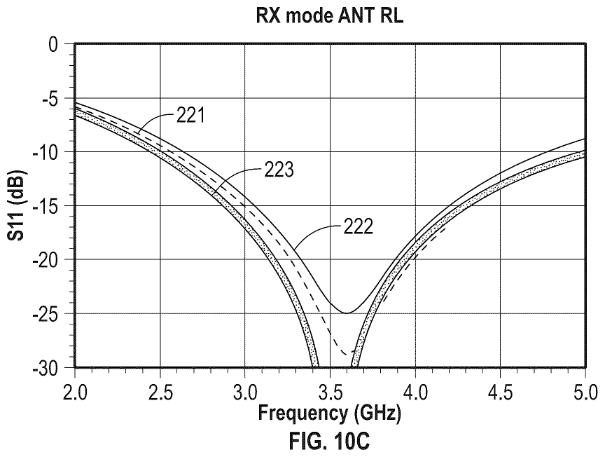

FIG. 10A is a graph of one example of return loss versus frequency in transmit mode for one implementation of a switch protected LNA. The graph includes a first plot 201 of return loss (corresponding to the four port S-parameter S11 in decibels) versus frequency for an LNA protected by a SPDT switch, a second plot 202 of return loss versus frequency for a switch protected LNA with a fixed input inductor, and a third plot 203 of return loss versus frequency for a switch protected LNA with inductor bypassing according to one embodiment. The graph depicts performance for 60 W transmit mode power handling in a 3.1 GHz to 4.2 GHz frequency band, with 150 fs effective Ron*Coff for the switch die. The same LNA device is used for comparison, with Cg=1 pF and gm=200 mA/V. Inductor quality factor (Q) is assumed to be about 20.

As shown in FIG. 10A, transmit mode return loss of the third plot 203 is comparable to that of the second plot 202, but the third plot 303 provides a wider transmit bandwidth.

FIG. 10B is a graph of one example of noise figure versus frequency in receive mode for one implementation of a switch protected LNA. The graph includes a first plot 211 of receive mode NF versus frequency for an LNA protected by a SPDT switch, a second plot 212 of receive mode NF versus frequency for a switch protected LNA with a fixed input inductor, and a third plot 213 of receive mode NF versus frequency for a switch protected LNA with inductor bypassing according to one embodiment.

As shown in FIG. 10B, receive mode NF of the third plot 313 is lower than that of the first plot 211 but greater than that of the second plot 212.

FIG. 10C is a graph of one example of return loss versus frequency in receive mode for one implementation of a switch protected LNA. The graph includes a first plot 221 of receive mode return loss versus frequency for an LNA protected by a SPDT switch, a second plot 212 of receive mode return loss versus frequency for a switch protected LNA with a fixed input inductor, and a third plot 213 of receive mode return loss versus frequency for a switch protected LNA with inductor bypassing according to one embodiment.

As shown in FIG. 10C, all three topologies have similar return loss in the receive mode to the antenna terminal ANT.

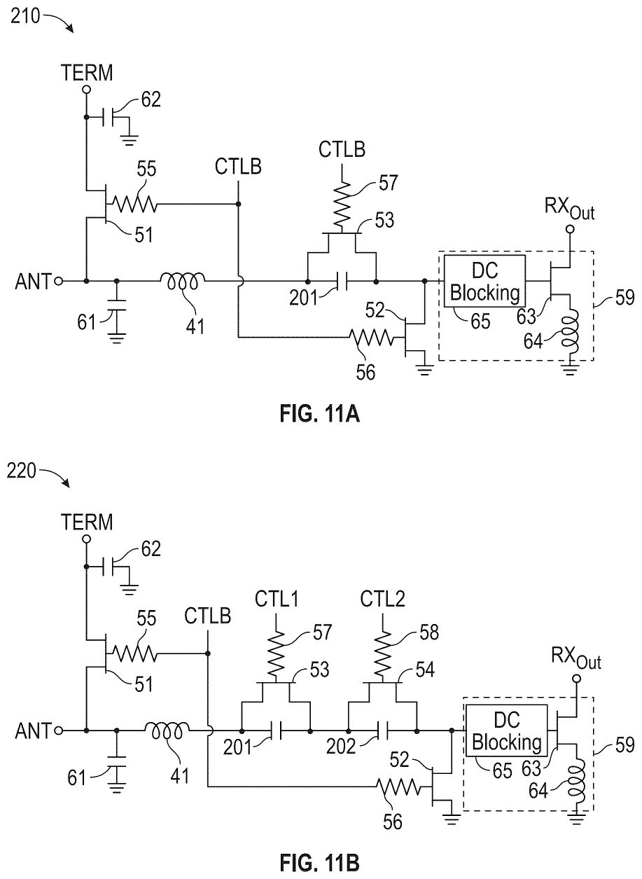

FIG. 11A is a schematic diagram of another embodiment of a switch protected LNA 210. The switch protected LNA 210 includes an antenna terminal ANT, a termination terminal TERM, a receive output terminal RX_{Out}, an input inductor 41, an input capacitor 201, an LNA 59, a series termination switch FET 51, a shunt protection switch FET 52, a bypass switch FET 53, a series termination switch gate resistor 55, a shunt protection switch gate resistor 56, a bypass switch gate resistor 57, an antenna terminal capacitor 61, and a termination terminal capacitor 62.

The switch protected LNA 210 of FIG. 11A is similar to the switch protected LNA 70 of FIG. 4, except that the switch protected LNA 210 omits the second input inductor 42 in favor of including the input capacitor 201. Additionally, the gate of the bypass switch FET 53 is controlled by the inverted control signal CTLB in FIG. 11A. As shown in FIG. 11A, the bypass switch FET 53 is electrically connected in parallel with the input capacitor 201 between the input inductor 41 and the input of the LNA 59.

When the bypass switch FET 53 is turned off by the inverted control signal CTLB in the receive mode, the capacitance of the input capacitor 201 resonates with the inductance of the input inductor 41 to provide a desired impedance for the input of the LNA 59 in the receive mode. For example, when the bypass switch FET 53 is turned off in the receive mode, an effectively lower inductance is provided for LNA matching and larger bandwidth. However, when the bypass switch FET 53 is turned on by the inverted control signal CTLB in the transmit mode, the input capacitor 201 is bypassed to provide a large inductance (corresponding to an inductance of the input inductor 41) for providing wide bandwidth for the transmit mode.

FIG. 11B is a schematic diagram of another embodiment of a switch protected LNA 220. The switch protected LNA 220 includes an antenna terminal ANT, a termination terminal TERM, a receive output terminal RX_{Out}, an input inductor 41, a first input capacitor 201, a second input capacitor 202, an LNA 59, a series termination switch FET 51, a shunt protection switch FET 52, a first bypass switch FET 53, a second bypass switch FET 54, a series termination switch gate resistor 55, a shunt protection switch gate resistor 56, a first bypass switch gate resistor 57, a second bypass switch gate resistor 58, an antenna terminal capacitor 61, and a termination terminal capacitor 62.

The switch protected LNA 220 of FIG. 11B is similar to the switch protected LNA 210 of FIG. 11A, except that the switch protected LNA 220 of FIG. 11B further includes the second bypass switch FET 54 that is connected in parallel to the second input capacitor 202. Additionally, the gate of the first bypass switch FET 53 receives a first control signal CTL1 through the first bypass switch gate resistor 57, while the gate of the second bypass switch FET 54 receives a second control signal CTL2 through the second bypass switch gate resistor 58.

By controlling the first control signal CTL1 and the second control signal CTL2, different amounts of capacitance can be provided to tune the resonance arising from the selected capacitance value and an inductance of the input inductor 41.

For example, by turning on both the first bypass switch FET 53 and the second bypass switch FET 54, both the first input capacitor 201 and the second input capacitor 202 can be bypassed to set the capacitance to a first capacitance value. Additionally, by turning off both the first bypass switch FET 53 and the second bypass switch FET 54, the capacitance can be set to a second capacitance value. Furthermore, a third capacitance value and a fourth capacitance value can be obtained by turning on just one of the first bypass switch FET 53 or the second bypass switch FET 54.

The switch protected LNA 11B provides flexible control suitable for providing controls for tuning to different frequency bands.

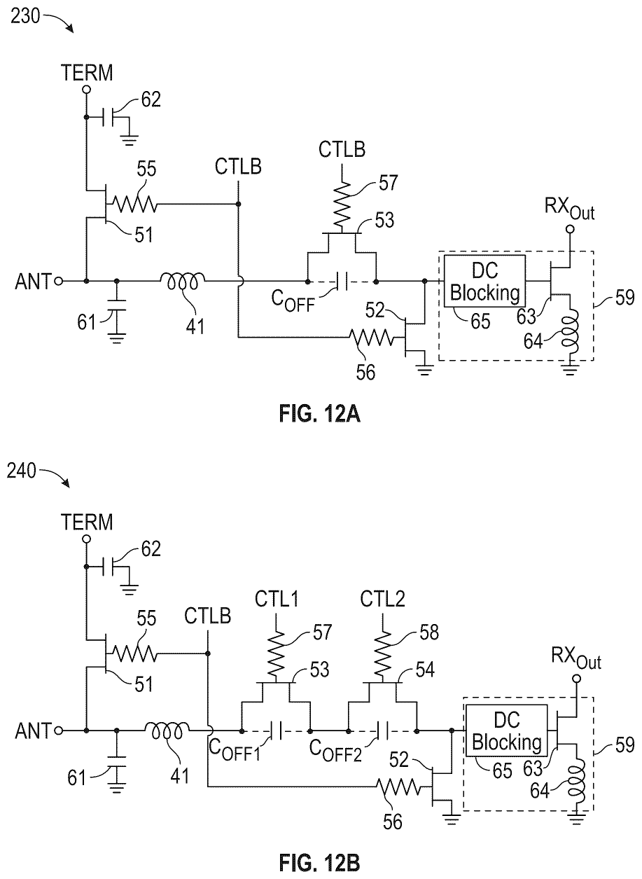

FIG. 12A is a schematic diagram of another embodiment of a switch protected LNA 230. The switch protected LNA 230 includes an antenna terminal ANT, a termination terminal TERM, a receive output terminal RX_{Out}, an input inductor 41, an LNA 59, a series termination switch FET 51, a shunt protection switch FET 52, a bypass switch FET 53, a series termination switch gate resistor 55, a shunt protection switch gate resistor 56, a bypass switch gate resistor 57, an antenna terminal capacitor 61, and a termination terminal capacitor 62.

The switch protected LNA 230 of FIG. 12A is similar to the switch protected LNA 210 of FIG. 11A, except that the switch protected LNA 230 omits the input capacitor 201 of FIG. 11A in favor of using an off-state capacitance COFF of the bypass switch FET 53 to resonate with the input inductor 41 when the switch protected LNA 230 operates in the receive mode. Thus, the bypass switch FET's own capacitance is used to provide a resonance in the receive mode and no explicit capacitor is included at these nodes in this embodiment.

FIG. 12B is a schematic diagram of another embodiment of a switch protected LNA 240. The switch protected LNA 240 includes an antenna terminal ANT, a termination terminal TERM, a receive output terminal RX_{Out}, an input inductor 41, an LNA 59, a series termination switch FET 51, a shunt protection switch FET 52, a first bypass switch FET 53, a second bypass switch FET 54, a series termination switch gate resistor 55, a shunt protection switch gate resistor 56, a first bypass switch gate resistor 57, a second bypass switch gate resistor 58, an antenna terminal capacitor 61, and a termination terminal capacitor 62.

The switch protected LNA 240 of FIG. 12B is similar to the switch protected LNA 220 of FIG. 11B, except that the switch protected LNA 240 omits the first input capacitor 201 and the second input capacitor 202 of FIG. 11B in favor of using off-state capacitances C_{OFF1} and C_{OFF2} of the first bypass switch FET 53 and the second bypass switch 54, respectively, to provide resonances. Thus, the first control signal CTL1 and the second control signal CTL2 can be controlled to set the capacitance value to one of four capacitance values.

### Applications

Devices employing the above-described schemes can be implemented into various electronic devices. Examples of electronic devices include, but are not limited to, RF communication systems, consumer electronic products, electronic test equipment, communication infrastructure, etc. For instance, one or more switch protected LNAs can be included in a wide range of RF communication systems, including, but not limited to, radar systems, base stations, mobile devices (for instance, smartphones or handsets), phased array antenna systems, laptop computers, tablets, and/or wearable electronics.

The teachings herein are applicable to RF communication systems operating over a wide range of frequencies, including not only RF signals between 100 MHz and 7 GHz, but also to higher frequencies, such as those in the X band (about 7 GHz to 12 GHz), the Kᵤ band (about 12 GHz to 18 GHz), the K band (about 18 GHz to 27 GHz), the Kₐ band (about 27 GHz to 40 GHz), the V band (about 40 GHz to 75 GHz), and/or the W band (about 75 GHz to 110 GHz). Accordingly, the teachings herein are applicable to a wide variety of RF communication systems, including microwave communication systems.

The RF signals amplified by the switch protected LNAs herein can be associated with a variety of communication standards, including, but not limited to, Global System for Mobile Communications (GSM), Enhanced Data Rates for GSM Evolution (EDGE), Code Division Multiple Access (CDMA), wideband CDMA (W-CDMA), 3G, Long Term Evolution (LTE), 4G, 5G and/or 6G, as well as other proprietary and non-proprietary communications standards.

### Conclusion

The foregoing description may refer to elements or features as being “connected” or “coupled” together. As used herein, unless expressly stated otherwise, “connected” means that one element/feature is directly or indirectly connected to another element/feature, and not necessarily mechanically. Likewise, unless expressly stated otherwise, “coupled” means that one element/feature is directly or indirectly coupled to another element/feature, and not necessarily mechanically. Thus, although the various schematics shown in the figures depict example arrangements of elements and components, additional intervening elements, devices, features, or components may be present in an actual embodiment (assuming that the functionality of the depicted circuits is not adversely affected).

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while the disclosed embodiments are presented in a given arrangement, alternative embodiments may perform similar functionalities with different components and/or circuit topologies, and some elements may be deleted, moved, added, subdivided, combined, and/or modified. Each of these elements may be implemented in a variety of different ways. Any suitable combination of the elements and acts of the various embodiments described above can be combined to provide further embodiments.

1. A switch protected low noise amplifier (LNA) comprising:
an antenna terminal configured to receive a radio frequency (RF) signal;
an LNA configured to amplify the RF signal;
a first input inductor;
a second input inductor, the first input inductor electrically connected between the antenna terminal and the second input inductor;
an inductor bypass switch electrically connected in parallel to the second input inductor; and
a shunt protection switch, the second input inductor electrically connected between the first input inductor and the shunt protection switch,
wherein the inductor bypass switch is configured to turn on and the shunt protection switch is configured to turn off in a receive mode of the switch protected LNA, and wherein the inductor bypass switch is configured to turn off and the shunt protection switch is configured to turn on in a transmit mode of the switch protected LNA.

2. The switch protected LNA of claim 1, wherein the inductor bypass switch includes a first terminal electrically connected to an input of the LNA and a second terminal electrically connected to a ground voltage through the shunt protection switch.

3. The switch protected LNA of claim 1, further comprising a termination terminal and a series termination switch electrically connected between the antenna terminal and the termination terminal, wherein the series termination switch is configured to turn on in the transmit mode and to turn off in the receive mode.

4. The switch protected LNA of claim 3, further comprising a shunt termination switch electrically connected between the termination terminal and a ground voltage, wherein the shunt termination switch is configured to turn off in the transmit mode and to turn on in the receive mode.

5. The switch protected LNA of claim 3, further comprising an antenna termination capacitor electrically connected between the antenna terminal and a ground voltage, and a termination terminal capacitor electrically connected between the termination terminal and the ground voltage.

6. The switch protected LNA of claim 1, further comprising a third input inductor and another inductor bypass switch electrically connected in parallel to the third input inductor, the third input inductor electrically connected between the second input inductor and the shunt protection switch.

7. The switch protected LNA of claim 1, wherein the shunt protection switch includes a first plurality of field-effect transistors in series, and the inductor bypass switch includes a second plurality of field-effect transistors in series.

8. The switch protected LNA of claim 1, wherein the low noise amplifier includes an input configured to receive the RF signal, a common source field-effect transistor, and at least one of a DC blocking component or a matching component connected between the input of the LNA and a gate of the common source field-effect transistor.

9. The switch protected LNA of claim 1, wherein an input of the LNA is electrically connected to a node between the second input inductor and the shunt protection switch.

10. The switch protected LNA of claim 1, wherein an input of the LNA is electrically connected to a node between the first input inductor and the second input inductor.

11. A front end system comprising:
a circulator; and
a switch protected low noise amplifier (LNA) comprising:
an antenna terminal configured to receive a radio frequency (RF) signal from a receive port of the circulator;
an LNA configured to amplify the RF signal;
a first input inductor;
a second input inductor, the first input inductor electrically connected between the antenna terminal and the second input inductor;
an inductor bypass switch electrically connected in parallel to the second input inductor; and
a shunt protection switch, the second input inductor electrically connected between the first input inductor and the shunt protection switch,
wherein the inductor bypass switch is configured to turn on and the shunt protection switch is configured to turn off in a receive mode of the switch protected LNA, and wherein the inductor bypass switch is configured to turn off and the shunt protection switch is configured to turn on in a transmit mode of the switch protected LNA.

12. The front end system of claim 11, wherein the inductor bypass switch includes a first terminal electrically connected to an input of the LNA and a second terminal electrically connected to a ground voltage through the shunt protection switch.

13. The front end system of claim 11, further comprising a termination terminal and a series termination switch electrically connected between the antenna terminal and the termination terminal, wherein the series termination switch is configured to turn on in the transmit mode and to turn off in the receive mode.

14. The front end system of claim 13, further comprising a shunt termination switch electrically connected between the termination terminal and a ground voltage, wherein the shunt termination switch is configured to turn off in the transmit mode and to turn on in the receive mode.

15. The front end system of claim 13, further comprising an antenna termination capacitor electrically connected between the antenna terminal and a ground voltage, and a termination terminal capacitor electrically connected between the termination terminal and the ground voltage.

16. The front end system of claim 13, further comprising a termination impedance electrically connected between the termination terminal and a ground voltage.

17. The front end system of claim 11, wherein an input of the LNA is electrically connected to a node between the second input inductor and the shunt protection switch.

18. The front end system of claim 11, wherein an input of the LNA is electrically connected to a node between the first input inductor and the second input inductor, the front end system further comprising an LNA input protection switch electrically connected between the input of the LNA and a ground voltage.

19. A method of protecting a low noise amplifier (LNA), the method comprising:
receiving a radio frequency (RF) signal at an antenna terminal,
turning on an inductor bypass switch and turning off a shunt protection switch in a receive mode of a switch protected LNA, wherein a first input inductor is electrically connected between the antenna terminal and a second input inductor, the second input inductor is electrically connected between the first input inductor and the shunt protection switch, and the inductor bypass switch is electrically connected in parallel to the second input inductor;
amplifying the RF signal using an LNA in the receive mode, the RF signal received by the LNA through the first input inductor; and
turning off the inductor bypass switch and turning on the shunt protection switch in a transmit mode of the switch protected LNA.

20. The method of claim 19, further comprising turning on a series termination switch in the transmit mode and turning off the series termination switch in the receive mode, the series termination switch electrically connected between the antenna terminal and a termination terminal.

21-40. (canceled)
